(19) United States
(12) Patent Application Publication
(10) Pub. No.: US 2023/0185976 A1
(43) Pub. Date: Jun. 15, 2023

(54) Systems and methods for editing and rendering tables

(71) Applicant: Canva Pty Ltd, Surry Hills (AU)

(72) Inventors: Luka Sam Kerr, Sydney (AU); Matthew David Anderson, Sydney (AU)

(73) Assignee: Canva Pty Ltd, Surry Hills (AU)

(21) Appl. No.: 18/070,009

(22) Filed: Nov. 28, 2022

(30) Foreign Application Priority Data
Dec. 10, 2021 (AU) 2021282538

(51) Int. Cl. G06F 30/12

(52) U.S. Cl. CPC G06F 30/12

(57) ABSTRACT

A computer implemented method for providing a graphical user interface for editing a design is described. A selection of a plurality of the design elements is received and a subset of the selected design elements is determined. Edit operations for the selected design elements are automatically selected based on the determined subset of the selected design elements. The design may be a table or include a table and the subset of selected design elements may be a category of borders forming the table.

### CROSS-REFERENCE TO RELATED APPLICATION

This application is a U.S. Non-Provisional Application that claims priority to Australian Patent Application No. 2021282538, filed Dec. 10, 2021, which is hereby incorporated by reference in its entirety.

### TECHNICAL FIELD

Aspects of the present disclosure are directed to computational systems and methods for rendering tables on a display device and to systems and methods for editing a table.

### BACKGROUND

Various computer implemented tools for creating, editing, and/or publishing designs that include one or more tables exist.

Typically, a given design tool provides various types of design elements that may form a part of, or be included in, a table. For example a design element may be a border of the table, which border may be around one more sides of the periphery of the table and/or around one or more sides of individual cells of the table.

The borders of a table may have a number of attributes, settable by a user of the design tool. An example attribute is the width of a line representing the border. Another example attribute is the colour of the border. The user may be able to set the attributes for a table as a whole and be able to set attributes for component parts of the table. The component parts may be designated by, for example, the selection of one or more cells, for example an individual cell, or a row or a column.

A developer of an application for creating and editing designs including tables needs to develop mechanisms for the tables to be edited, included a user interface.

### SUMMARY

Example embodiments described herein are directed to a computer implemented method for providing a graphical user interface for editing a design, the method including: causing display, on a display device, of a user interface for editing a design; causing display, in the user interface, of a design formed by a plurality of design elements, wherein each of the plurality of design elements is associated with one or more attribute values that define how the design element is displayed; receiving a selection of a plurality of the design elements; determining a subset of the selected design elements; and automatically selecting one or more first edit operations for the selected design elements based on the determined subset of the selected design elements and not automatically selecting one or more second edit operations for the selected design elements based on the determined subset of the selected design elements; and in response to receiving an edit command, editing at least one attribute value of the subset of the selected design elements in accordance with the one or more first edit operations.

The disclosed embodiments may have particular application to designs that are tables. The detailed description is made with reference this application. The disclosed embodiments may however have application to other designs, including in particular designs in which there are categories of design elements that are usefully edited together. By way of illustration, an example category of design elements of a table is the left border of cells in the able and another example is the outside border of cells in the table.

In the context of a table, the present disclosure relates to embodiments of a computer implemented method for providing a graphical user interface for editing a table, the method including: causing display, on a display device, of a user interface for editing a table; causing display, in the user interface, of a table formed by a plurality of cells, each cell having a plurality of borders, wherein each of the plurality borders is associated with one or more attribute values that define how the border is displayed; receiving a selection of one or more cells; determining at least one subset of borders of the selected cells; automatically selecting one or more first border edit operations based on the determined subset of borders and not automatically selecting one or more second border edit operations based on the determined subset borders; and in response to receiving an edit command, editing at least one attribute value of the subset of borders in accordance with the one or more first edit operations.

Example embodiments described herein are directed to a computer processing system including a processing unit, a display and a non-transient computer-readable storage medium storing instructions, which when executed by the processing unit, cause the processing unit to edit a design or table according to a method described in the immediately preceding paragraphs or according to a method described in the following description.

Example embodiments described herein are directed to a non-transient computer-readable storage medium storing instructions, which when executed by a processing unit, cause the processing unit to edit a design or table, by performing the method described in the immediately preceding paragraphs or a method described in the following description.

### BRIEF DESCRIPTION OF THE DRAWINGS

FIG. 1 is a diagram depicting a networked environment in which various features of the present disclosure may be implemented.

FIG. 2 is a block diagram of a computer processing system configurable to perform various features of the present disclosure.

FIG. 3 depicts an example design creation graphical user interface.

FIG. 4 depicts example menus from a design creation graphical user interface.

FIGS. 5 to 9 show flow diagrams of processes that may be performed by a computer processing system, for example by the computer processing system of FIG. 2.

### DETAILED DESCRIPTION

In the description numerous specific details are set forth, including in and with reference to the accompanying drawings, in order to provide a thorough understanding of the present invention. It will be apparent, however, that the present invention may be practiced without these specific details. In some instances, well-known structures and devices are shown in block diagram form in order to avoid unnecessary obscuring.

Design creation tools can provide an array of options that enable users add design elements to a design incorporating a table and to manipulate design elements once added to a design, including changing one or more attributes of one or more design elements. A common function performed for a table is to select the values of attributes forming a border of one or more cells of the table or of the table as a whole. An application providing a design creation tool therefore preferably provides an effective and efficient mechanism to enable users to create and edit tables.

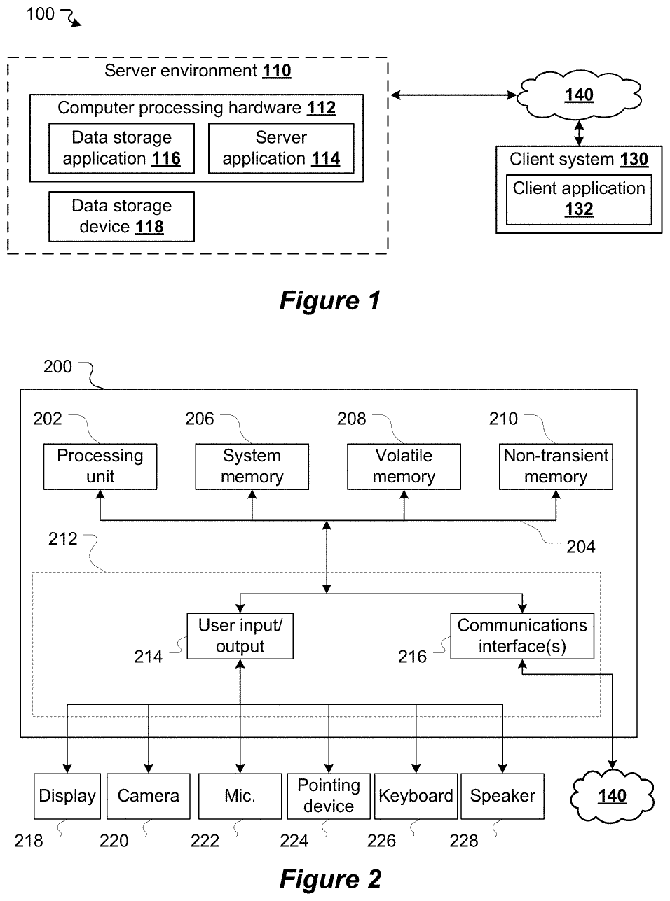

The present disclosure provides a mechanism, in particular a software application, for rendering or editing a table in a design. The design may consist only of the table or the table may form part of a design that includes other design elements. The mechanism for rending a table in a design is provided by a design platform. In the present embodiments, the design platform is provided by a client server architecture, such as that shown in networked environment 100 of FIG. 1.

The following description is made with reference to a rectangular table, including a rectangular outer peripheral shape and rectangular cell shapes. The examples show a uniform cell size. However, the present disclosure is not limited to such rectangular tables and the processes for rendering a table may be applied to other table and cell shapes and to non-uniform tables.

The networked environment 100 includes a server environment 110 and a client system 130, which communicate via one or more communications networks 140 (e.g. the Internet).

Generally speaking, server environment 110 includes computer processing hardware 112 on which one or more applications are executed that provide server-side functionality to client applications. In the present example, the computer processing hardware 112 of the server environment 110 runs a server application 114 (which may also be referred to as a front end server application) and a data storage application 116.

The server application 114 operates to provide an endpoint for a client application, for example a client application 132 on the client system 130, which is accessible over communications network 140. To do so, the server application 114 may include one or more application programs, libraries, APIs or other software elements that implement the features and functions that are described herein, including for example to provide a design creation tool. By way of example, where the server application 114 serves web browser client applications, the server application 114 will be a web server which receives and responds to, for example, HTTP application protocol requests. Where the server application 114 serves native client applications, the server application 114 will be an application server configured to receive, process, and respond to API calls from those client applications

The server environment 110 may include both web server and application server applications allowing it to interact with both web and native client applications.

In addition to the specific functionality described herein, the server application 114 (alone or in conjunction with other applications) may provide additional functions that are typically provided by server systems—for example user account creation and management, user authentication, and/or other server side functions.

The data storage application 116 operates to receive and process requests to persistently store and retrieve data in data storage that is relevant to the operations performed/services provided by the server environment 110. Such requests may be received from the server application 114, other server environment applications, and/or (in some instances) directly from client applications such as the client application 132. Data relevant to the operations performed/services provided by the server environment may include, for example, user account data, design data (i.e. data describing designs that have been created by users), data defining design assets and/or other data relevant to the operation of the server application 114. Design assets may be stored in one or more libraries and may include, for example, various types of assets that users can use to create designs. Such assets may include, for example, design elements, design templates, predefined styles or formatting schemes, and/or other assets. The data storage is provided by one or more data storage devices and the example of FIG. 1 shows a data storage device 118 in the server environment 110 and the following description is made with reference to this device.

The data storage application 116 may, for example, be a relational database management application or an alternative application for storing and retrieving data from the data storage device 118. The data storage application 116 stores data to and retrieves data from one or more non transient (or persistent) data storage devices 118—e.g. non-transient computer readable storage devices such as hard disks, solid state drives, tape drives, or alternative computer readable storage devices.

In the server environment 110, the server application 114 persistently stores data to the data storage device 118 via the data storage application 116. In alternative implementations, however, the server application 114 may be configured to directly interact with the data storage device 118 to store and retrieve data, in which case a separate data storage application may not be needed. Furthermore, while a single data storage application 116 is described, the server environment 110 may include multiple data storage applications. For example one data storage application 116 may be used for user data, another for design data, and one or more further data storage applications 116 used for design element data. In this case, each data storage application may interface with one or more shared data storage devices 118 and/or one or more dedicated data storage devices 118, and each data storage application may receive/respond to requests from various server-side and/or client-side applications (including, for example server application 114).

As noted, the server application 114 and data storage application 116 run on (or are executed by) computer processing hardware 112. Computer processing hardware 112 includes one or more computer processing systems. The precise number and nature of those systems will depend on the architecture of the server environment 110.

For example, in one implementation a single server application 114 runs on its own computer processing system and a single data storage application 116 runs on a separate computer processing system. In another implementation, a single server application 114 and a single data storage application 116 run on a common computer processing system. In yet another implementation, server environment 110 may include multiple server applications running in parallel (on one or multiple computer processing systems).

Communication between the applications and computer processing systems of the server environment 110 may be by any appropriate means, for example direct communication or networked communication over one or more local area networks, wide area networks, and/or public networks (with a secure logical overlay, such as a VPN, if required).

The present disclosure describes various operations that are performed by applications of the server environment 110. Generally speaking, however, operations described as being performed by a particular application (e.g. server application 114) could be performed by one or more alternative applications, and/or operations described as being performed by multiple separate applications could in some instances be performed by a single application.

The client system 130 hosts the client application 132 which, when executed by the client system 130, configures the client system 132 to provide client-side functionality/interact with sever environment 110 (or, more specifically, the server application 114 and/or other application provided by the server environment 110). Via the client application 132, a user can perform various operations such as creating, editing, saving, retrieving/accessing, publishing, and sharing documents including one or more designs. Such operations may be performed solely by the client application 132, or may involve the client application 132 communicating with the server environment 110 for processing to be performed there (e.g. by the server application 114). It will be appreciated that where the relevant operations, in particular the operations to provide a design creation tool as described herein, are performed solely by the client application 132, then there may be no need for communication with or the presence of the server environment 110.

The client application 132 may be a general web browser application which accesses the server application 114 via an appropriate uniform resource locator (URL) and communicates with the server application 114 via general world-wide-web protocols (e.g. http, https, ftp). Alternatively, the client application 132 may be a native application programmed to communicate with server application 114 using defined application programming interface (API) calls.

A given client system such as 130 may have more than one client application 132 installed and executing thereon. For example, a client system 130 may have a (or multiple) general web browser application(s) and a native client application.

The techniques and operations described herein are performed by one or more computer processing systems.

By way of example, the client system 130 may be any computer processing system which is configured or is configurable by hardware and/or software to offer client-side functionality. A client system 130 may be a desktop computer, laptop computers, tablet computing device, mobile/smart phone, or other appropriate computer processing system. Similarly, the applications of the server environment 110 are also executed by one or more computer processing systems. Server environment computer processing systems will typically be server systems, though again may be any appropriate computer processing systems.

FIG. 2 provides a block diagram of a computer processing system 200 configurable to implement embodiments and/or features described herein. The system 200 is a general purpose computer processing system. It will be appreciated that FIG. 2 does not illustrate all functional or physical components of a computer processing system. For example, no power supply or power supply interface has been depicted, however system 200 will either carry a power supply or be configured for connection to a power supply (or both). It will also be appreciated that the particular type of computer processing system will determine the appropriate hardware and architecture, and alternative computer processing systems suitable for implementing features of the present disclosure may have additional, alternative, or fewer components than those depicted.

The computer processing system 200 includes at least one processing unit 202. The processing unit 202 may be a single computer processing device (e.g. a central processing unit, graphics processing unit, or other computational device), or may include a plurality of computer processing devices. In some instances, where a computer processing system 200 is described as performing an operation or function all processing required to perform that operation or function will be performed by processing unit 202. In other instances, processing required to perform that operation or function may also be performed by remote processing devices accessible to and useable by (either in a shared or dedicated manner) system 200.

Through a communications bus 204 the processing unit 202 is in data communication with a one or more machine readable storage (memory) devices which store computer readable instructions and/or data which are executed by the processing unit 202 to control operation of the processing system 200. In this example the system 200 includes a system memory 206 (e.g. a BIOS), volatile memory 208 (e.g. random access memory such as one or more DRAM modules), and non-transient memory 210 (e.g. one or more hard disk or solid state drives).

The system 200 also includes one or more interfaces, indicated generally by 212, via which system 200 interfaces with various devices and/or networks. Generally speaking, other devices may be integral with the system 200, or may be separate. Where a device is separate from system 200, connection between the device and system 200 may be via wired or wireless hardware and communication protocols, and may be a direct or an indirect (e.g. networked) connection.

Wired connection with other devices/networks may be by any appropriate standard or proprietary hardware and connectivity protocols. For example, system 200 may be configured for wired connection with other devices/communications networks by one or more of: USB; eSATA; Ethernet; HDMI; and/or other wired connections.

Wireless connection with other devices/networks may similarly be by any appropriate standard or proprietary hardware and communications protocols. For example, the system 200 may be configured for wireless connection with other devices/communications networks using one or more of: BlueTooth; WiFi; near field communications (NFC); Global System for Mobile Communications (GSM), and/or other wireless connections.

Generally speaking, and depending on the particular system in question, devices to which the system 200 connects—whether by wired or wireless means—include one or more input devices to allow data to be input into/received by the system 200 and one or more output devices to allow data to be output by system 200. Example devices are described below, however it will be appreciated that not all computer processing systems will include all mentioned devices, and that additional and alternative devices to those mentioned may well be used.

For example, the system 200 may include or connect to one or more input devices by which information/data is input into (received by) the system 200. Such input devices may include keyboard, mouse, trackpad, microphone, accelerometer, proximity sensor, GPS, and/or other input devices. The system 200 may also include or connect to one or more output devices controlled by the system 200 to output information. Such output devices may include devices such as a display (e.g. a LCD, LED, touch screen, or other display device), speaker, vibration module, LEDs/other lights, and/or other output devices. The system 200 may also include or connect to devices which may act as both input and output devices, for example memory devices (hard drives, solid state drives, disk drives, and/or other memory devices) which the system 200 can read data from and/or write data to, and touch screen displays which can both display (output) data and receive touch signals (input).

By way of example, where the system 200 is the client system 130 it may include a display 218 (which may be a touch screen display), a camera device 220, a microphone device 222 (which may be integrated with the camera device), a pointing device 224 (e.g. a mouse, trackpad, or other pointing device), a keyboard 226, and a speaker device 228.

The system 200 also includes one or more communications interfaces 216 for communication with a network, such as network 140 of environment 100 (and/or a local network within the server environment 110). Via the communications interface(s) 216, system 200 can communicate data to and receive data from networked systems and/or devices.

The system 200 may be any suitable computer processing system, for example, a server computer system, a desktop computer, a laptop computer, a netbook computer, a tablet computing device, a mobile/smart phone, a personal digital assistant, or an alternative computer processing system.

The system 200 stores or has access to computer applications (also referred to as software or programs)—i.e. computer readable instructions and data which, when executed by the processing unit 202, configure the system 200 to receive, process, and output data. Instructions and data can be stored on non-transient memory 210. Instructions and data may be transmitted to/received by the system 200 via a data signal in a transmission channel enabled (for example) by a wired or wireless network connection over an interface, such as communications interface 216.

Typically, one application accessible to system 200 will be an operating system application. In addition, system 200 will store or have access to applications which, when executed by the processing unit 202, configure system 200 to perform various computer-implemented processing operations described herein. For example, and referring to the networked environment of FIG. 1 above, server environment 110 includes one or more systems which run a server application 114, a data storage application 116. Similarly, client system 130 runs a client application 132.

In some cases part or all of a given computer-implemented method will be performed by the system 200 itself, while in other cases processing may be performed by other devices in data communication with system 200.

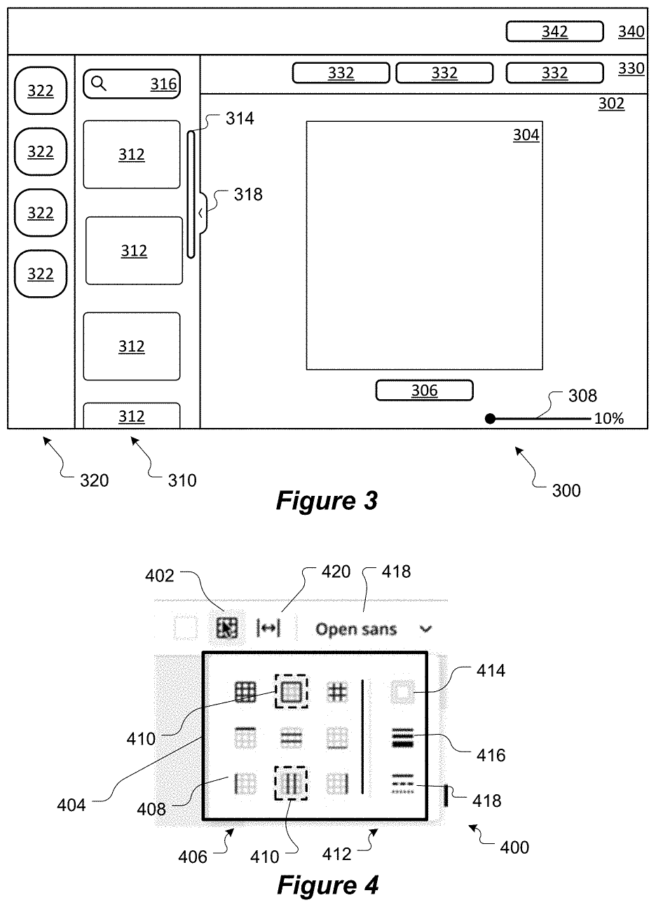

The client application 132 configures the client system to provide a design creation user interface of a design creation tool. Generally speaking, a design creation user interface (UI) will allow a user to create, edit, and output designs. To illustrate the types of features that client application 132 may provide, FIG. 3 provides one example of a design creation user interface, which example is in the form of a graphical user interface (GUI) 300. Alternative interfaces, with alternative layouts and/or providing alternative tools and functions, are possible.

The GUI 300 includes a design preview area 302 in which a canvas 304 is shown. The canvas 304 is used to display a page of a design that is being worked with (e.g. created, edited, output). In particular, the design will consist or include one or more tables (not shown in FIG. 3). In this example, an add page control 306 is provided, which if activated by a user, causes a new page to be added to the design being created. A zoom control 308 is also provided, by which a user can interact with to zoom into/out of the page currently displayed by the canvas 304.

The GUI 300 also includes an asset preview area 310. The asset preview area 310 displays previews 312 of assets that are made available (e.g. by server environment 110) to users to assist in creating designs. Example assets that may be available for selection from the asset preview area 310 are tables with a selection of available default table formats. For instance, one preview 312 may be a preview of a table in which all cells are formatted the same and another may preview a table format in which the first/uppermost row of the table has one format consistent with column headings and the other rows have a second format, consistent with column entries. Another example asset that may be available for selection from the asset preview area 310 are charts. For instance, one preview 312 may be a preview of a pie chart, another a preview of a bar chart and a third a preview of a line graph. In some embodiments a chart is generated by a combination of a user selecting a table and selecting a preview of the type of chart the user requires.

In this example, the preview area 310 displays a scroll control 314 allowing a user to scroll through previews 312. Scroll control 314 may be hidden when user focus is not in the preview area 310. Preview area 310 also includes a search control 316 via which a user can submit search data (e.g. a string of characters) to search for particular design assets. Previews 312 of the search results returned are then displayed in the preview area 310. In this example, a hide preview area control 318 is provided which can be activated to hide the asset preview area 310 (serving to enlarge the design preview area 302).

The GUI 300 also includes a type selection area 320, which displays a plurality of type selection controls 322. The type selection controls 322 may be activated by a user to select a type of design asset for which previews 312 are displayed (and can be searched for) in asset preview area 310. By way of example, type selection controls 322 may be provided for types such as design templates, design elements, photos (e.g. raster graphics), graphics (e.g. vector graphics), text, audio, video, styles, and/or other types. The previews of tables (and in some embodiments the previews of charts) may be displayed responsive to selection of a selection control 322 for design elements.

The GUI 300 also includes an adaptive control area 330 for displaying adaptive controls 332. Adaptive controls 332 change depending on the type of design element that is currently selected/being interacted with by a user. For example, if a text element is selected adaptive controls 332 such as font style, type, size, position/justification, and/or other font related controls may be displayed. Alternatively, if a table graphic element is selected, adaptive controls 332 such as fill, line style, line width, transparency, delete column, delete row, add column, add row, move column, move row, size column, size row and/or other table graphic related controls may be displayed. An adaptive control 332 may be a menu, which when selected displays a menu of controls. In other embodiments, one or more controls relating to a table are not adaptive controls and are instead displayed on user command or are always displayed as part of the GUI 300.

The GUI 300 also includes an additional control area 340 which displays additional controls 342. Any appropriate additional controls 342 may be displayed, for example controls to save, download, print, share, resize, and/or perform other actions.

Once created, a user may output a design in various ways. For example, client application 132 may provide a user with options to output a design by one or more of: saving the design to local memory of client system 130 (e.g. non-transient memory 210); saving the design to the data storage device 118 of server environment 110; printing the design to a printer (local or networked); communicating the design to another user (e.g. by email, instant message, or other electronic communication channel); publishing the design to a social media platform or other service (e.g. by sending the design to a third party server system with appropriate API commands to publish the design); and/or by other output means.

FIG. 4 shows an example of a portion of a screen display, a screen display portion 400, which may be displayed as part of a GUI of an application, for example as part of the GUI 300.

The screen display portion includes a selectable icon 402, for toggling the display of a menu 404. The icon 402 may be an adaptive control, for example an adaptive control 332 described with reference to FIG. 3, displayed when a table is selected in a currently displayed design. As described above, in other embodiments the icon 402 is not an adaptive control. In FIG. 4 the menu 404 includes two submenus. Further adaptive controls or other controls may be displayed while displaying the icon 402, for example an icon 420 for invoking functionality to change a width of a cell or column in a table and a field 422 for displaying and selecting a font to apply to text within a table.

A first submenu 406 includes nine selectable items 408 (only one indicated by a reference numeral in FIG. 4, the item to select the left border), displayed in the example of FIG. 4 in a three-by-three grid. These nine selectable items allow for selection of various types of border of a table. Working from the top left across each row, the options for border type include: a) every border of every selected cell, b) the outer borders formed by the selected cells, c) the inner borders formed by the selected cells, d) the top borders formed by the selected cells, e) the inner horizontal borders formed by the selected cells, f) the bottom borders formed by the selected cells, g) the left borders formed by the selected cells, h) the inner vertical borders formed by the selected cells, and i) the right borders formed by the selected cells. In other embodiments less or more or alternative border options may be provided in the submenu 406. A selection indicator 410 is displayed on a selectable item 408 to indicate when it is selected. In some embodiments the application providing the submenu 406 allows a plurality of the selectable items 408 to simultaneously have a status of selected. In this case a corresponding plurality of selection indicators 410 may be displayed. FIG. 4 shows an example of two selectable items 408 being selected.

A second submenu 412 includes three selectable items for affecting an attribute of a border or collection of borders. In the example shown, the selectable items are a colour selector 414, a line weight selector 416 and a line style selector 418. In other embodiments less or more or alternative options may be provided in the submenu 412. In other embodiments the items of submenu 406 and the items of submenu 412 are displayed in separate menus. Each separate menu may be displayed, for example, responsive to selection of an adaptive control 332.

By way of example, selection of the colour selector 414 may cause a colour palette to be displayed, from which a colour can be selected for the selected borders, as indicated by the one or more selection indicators 410. Responsive to a selection of a colour, that colour may be applied to the selected borders. In another example, one type of selection action with respect to the colour selector 414, for example hovering a cursor over the colour selector 414, causes the colour palette to be displayed to enable a colour to be selected and another type of selection action with respect to the colour selector 414, for example a click action while the cursor is over the colour selector 414, causes the currently selected colour to be applied. In other examples, the colour selector 414 applies a colour that has been selected using other user interface items, for example another adaptive control 332. In that case the selectable item may be more aptly described as a colour applicator, rather than a colour selector.

Also by way of example, selection of the line weight selector 416 may cause a menu of line weights to be displayed, from which a line weight can be selected for the selected borders, as indicated by the one or more selection indicators 410. Responsive to a selection of a line weight, that weight may be applied to the selected borders. In another example, one type of selection action with respect to the line weight selector 416, for example hovering a cursor over the line weight selector 416, causes the menu of weights to be displayed to enable a weight to be selected and another type of selection action with respect to the line weight selector 416, for example a click action while the cursor is over the line weight selector 416, causes the currently selected weight/style to be applied. In other examples, the line weight selector 416 applies a weight that has been selected using other user interface items, for example another adaptive control 332. The line style selector 418 may operate in the same manner as the line weight selector 416, except for being used to edit line style instead of line weight.

In some embodiments of an application providing a design creation tool, a user edits borders of a table by a process including selecting one or more cells in a table, selecting the required attribute values by selecting one or more items from submenu 412 and then applying the selected attribute values to a required set of borders by selecting one or more border types from submenu 406. For example, a user may select a column of the table, select a colour using the colour selector 414 from submenu 412 and then apply that colour to all borders of the selected cells by selecting the “all borders option” from submenu 406. This process can be manually intensive, involving several selection operations. Additionally, the process may be unintuitive, at least for some users.

Embodiments of the present disclosure provide alternative processes for editing borders of a table. These embodiments include a process of a computer processing system providing the design creation tool automatically determining one or more borders to select, from a user selected one or more cells. In other words, the computer processing system automatically selects one or more items from submenu 406. The user may then proceed with the selection, by selecting an attribute value (e.g. colour or line weight or line style) to apply to the selected borders. This process may reduce the required number of selection items, at least over multiple editing operations. The processes may involve accommodating user selections of one or more borders different to the border(s) that have been automatically selected.

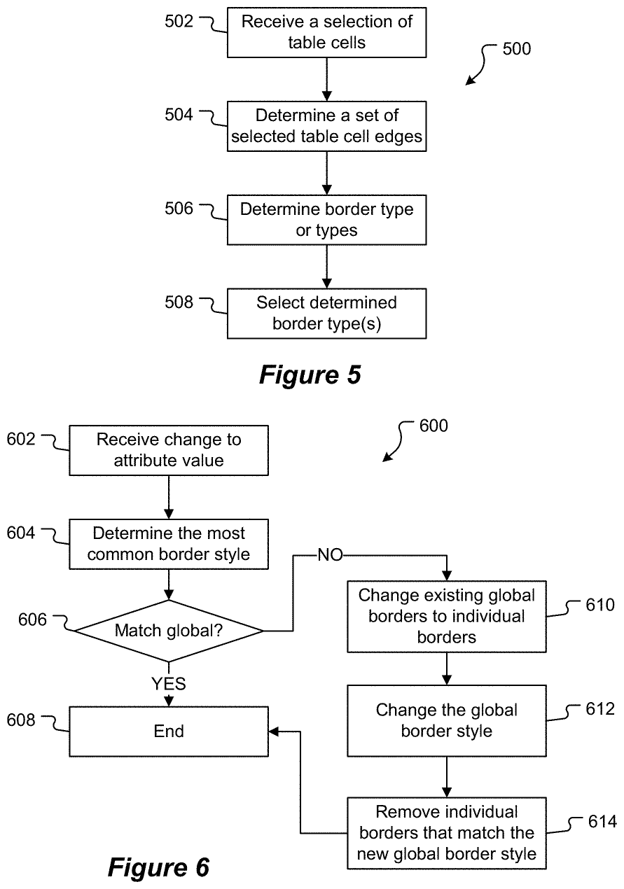

FIG. 5 shows a flow diagram of a process 500 for an application to automatically select one or more border types. The process may be performed whilst a computer processing system, for example the computer processing system 200, is causing the display, on a display device, of a table. For example, the process may be performed whilst a table is displayed on the canvas 304 of the GUI 300.

At step 502, the computer processing system receives a selection of one or more table cells. For example, the received selection may be by the user individually selecting individual cells, by selecting a group of cells such as a row or column, or selecting all cells of the table. In some embodiments, adaptive controls of the GUI are updated responsive to the selection. For example the icon 402 may appear in the adaptive control area 330 responsive to the selection.

At step 504, the computer processing system determines a set of table cell edges for the selected cells, based on the received selection of one or more table cells. For a plurality of options for border type, up to all of the available options for border type, the computer processing system determines the cell edges of that type for the one or more table cells of the received selection. The plurality of options for border type may correspond to the options available for selection by the user, for example the set of options presented in submenu 406 described with reference to FIG. 4. For example, step 504 includes determining the sets of: a) every border of every selected cell, b) the outer borders formed by the selected cells, c) the inner borders formed by the selected cells, d) the top borders formed by the selected cells, e) the inner horizontal borders formed by the selected cells, f) the bottom borders formed by the selected cells, g) the left borders formed by the selected cells, h) the inner vertical borders formed by the selected cells, and i) the right borders formed by the selected cells.

Whilst in some embodiments steps 504, 506 and 508 are performed each time a selection of table cells is received by the computer processing system, in other embodiments these steps are performed when an automatic selection of border types is required, for example in response to selection of the icon 402. Performing the process when required may result in better computational efficiency.

At step 506, the computer processing system determines which border type or types to automatically select. Step 506 includes comparing each set of table cell edges to a reference. In some embodiments the reference is one or more attribute values of a cell border that have been or are determined by the computer processing system based on characteristics of the table from which the selection received in step 502 was made.

The reference may be determined by the computer processing system based on the attribute values for the borders of the entire table. For example, the computer processing system may determine a set of majority border attributes for the table. The set of majority border attributes may include one or more of colour, weight and style. For instance the reference may be the most common border colour used in the table, or the most common combination of border colour and line weight used in the table, or the most common combination of border colour, line weight and line style used in the table. The majority may be determined by a count operation and a compare operation. The reference may be formed by other attributes or other combinations of attributes. In other embodiments the determination of the reference is not dictated by a simple majority across the entire table. For example, in other embodiments the border type for the peripheral edge is used as the reference and in other embodiments some edges (e.g. the external edges) are given more weight than others (e.g. internal edges) for determining the reference.

In some embodiments a border type is determined as a border type to automatically select, when a threshold number of cell edges in the set of table cell edges corresponding to that border type satisfy a comparison criterion or set of comparison criteria with the reference. In some embodiments a border type is determined as a candidate border type for automatically selection, when a threshold number of cell edges in the set of table cell edges corresponding to that border type satisfy a comparison criterion or set of comparison criteria with the reference. Further processing then determines which of the candidate border types to automatically select.

In some embodiments the threshold number of cell edges is all of the cell edges in the set of table cell edges. In some embodiments the threshold is less than all cell edges, for example a majority of cell edges or a threshold between a majority and all cell edges. In some embodiments, the threshold number of cell edges is all of the cell edges when the comparison criterion or criteria results in one or more border types being determined for automatic selection. When a threshold of all cell edges does not result in one or more border types for automatic selection, the threshold may be progressively reduced until at least one border type is determined for automatic selection.

In some embodiments a border type is determined as a border type or border type candidate to automatically select, when every cell edge in the set of table cell edges corresponding to that border type is unique relative to the reference. In some embodiments a cell edge is determined to be unique if all of its attribute values corresponding to attributes in the reference are different to the attribute values of the reference. For example, if the reference is a red line, three points in weight, then a blue line of one point in weight is determined to be unique, whereas a blue line of three points in weight is not. In other embodiments a cell edge is determined to be unique if any one of its attribute values is different to the reference. In these embodiments a blue line of three points in weight is determined unique to a red line of three points in weight.

In some embodiments all border types determined as a border type to automatically select according to the comparison criterion or criteria are selected in step 508. The selection of step 508 may be communicated to a user of the computer processing system. The computer processing system may display a GUI with one or more selection indicators that indicate the selected border types. An example selection indicator 410 was described with reference to GUI 300.

In other embodiments, border types satisfying the comparison criterion or criteria are subject to further selection in step 506. In this instance the result of applying the comparison criterion or criteria is a set of candidate border types.

In some embodiments the further selection minimises the number of border types that are selected, having regard to combinations of border type selections that result in selection of the same borders. For example, if each of the four border options for ‘left’, ‘right’, ‘top’ and ‘bottom’ were all determined as candidate border types, then the further selection process selects the ‘outer’ border option as a single selected option, instead of the four border options.

In some embodiments, the reference utilised in step 506 is a “global” table border style. In other words the value(s) of the attribute(s) forming the reference utilised in step 506 are those of the global table border style.

A global table border style may be viewed as representing a default style for borders of the table. For example, when a design template for a table is provided by the application, that design template may have attribute values for the borders of the cells. The global table border style may reflect those attribute values. Use of a global table border style may create efficiencies. For example, if the design template for the table includes visible borders only around the periphery of the table, then a user may select an interior border and make a selection or provide a command to apply a visible border to that interior border. The application may change the visible border to that of the global table border style, without the user having to find and select the attribute values for that style. In another example, the data defining the table may reference the global table border style and reference the borders that vary from the global table border style. Each border not referenced as varying from the global table border style is rendered according to the global table border style. This may require less data than defining each border individually.

In some embodiments the global table style is updated responsive to certain edits being made to a table. In some embodiments, the edits that cause an update to the global table style correspond to edits that cause an update to the reference. For example, as described above, in some embodiments the reference utilised in step 506 is one or more majority attribute values for the cell borders of the table from which the selection received in step 502 was made. In that instance, the global table style for a table is updated as required to correspond to the majority attribute values in that table.

In some embodiments the reference used in the processes for automatically selecting border types includes all attributes in the global table style that define the table borders. In other embodiments the reference includes some, but less than all attributes in the global table style.

FIG. 6 shows a flow diagram of a process 600 for an application to automatically update the global table style. As described above, in some embodiments the process 600 is also a process for an application to automatically update the reference utilised in step 506. The process may be performed whilst a computer processing system, for example the computer processing system 200, is causing the display, on a display device, of a table. For example, the process may be performed whilst a table is displayed on the canvas 304 of the GUI 300.

In step 602, one or more changes to one or more attribute values of one or more cell edges in a table is received. The change(s) may be received, for example, responsive to a user selecting items in the menu 404 of GUI 300, as described above. The rendering of the table displayed on the canvas 304 may be updated responsive to the received one or more changes.

In step 604, the computer processing system determines the most common border style in the table. The border style may be specified by a combination of the values of all attributes that define borders. For example the border style may be specified by line colour, line weight and line style. The global table style may be specified by less or more or different attributes in other embodiments. It will be appreciated that any attribute not included in the global style may require further definition, for example when changed in a table to something different from a template. The determination of the most common border style in the table may be performed by reading the attribute values of each border in the table, and incrementing a count for a combination of attribute values of that border. Once the attribute values for all borders have been read and counted, the computer processing system determines the combination of attribute values with the highest count.

In step 606 the computer processing system determines if the most common border style matches a current global table style. The current global table style is stored in memory by the computer processing system, for access when required. For example, on the addition of a table to the canvas 304, data defining the global table style of the table as added may be stored in memory. This data may be determined by the computer processing system, for example as described with reference to step 604, or may be pre-set for the table that has been added, for example as part of the data defining or associated with a template for the table.

If the most common border style matches the current global table style, then the process ends at step 608. The process may recommence on receipt of a further change to an attribute value, as per step 602.

If the most common border style does not match the current global table style, then a process for changing the global table style is initiated. In step 610 the computer processing system updates the data defining the table to change any existing borders defined by the global table style to individually defined borders. In other words, the data definition of the border line is changed from a direct or indirect reference to the global table style, to an explicit definition of the existing attributes of the border line. Step 610 avoids existing borders defined by the global table style being changed as a result of step 612.

In step 612 the data defining the global table style is changed to match the most common border style determined in step 604. The process may be completed by reading the previously stored data indicating the most common border style and writing the attribute values to one or more fields of the relevant application to define the global table style.

In step 614 the computer processing system reads the attributes of the table borders that have been individually defined and determines if they match the new global border style, as set in step 612. If a border line matches the new global border style, the individual definition of that border line is removed. The definition may be a null, with the application configured to use the global border style responsive to the null, or may be a reference that indicates that the global border style applies for that border line. After step 614 the process ends, awaiting the next attribute value change.

In some embodiments, an application providing a design creation tool allows for selection of cells in table that do not form a contiguous block of cells. Following selection of the cells, the design creation tools allows for borders of the selected cells to be edited, by changing one or more attribute values. The editing process may involve selecting a border type to which the changed attribute values are to be applied. As explained above, example border types include a) every border of every selected cell, b) the outer borders formed by the selected cells, c) the inner borders formed by the selected cells, d) the top borders formed by the selected cells, e) the inner horizontal borders formed by the selected cells, f) the bottom borders formed by the selected cells, g) the left borders formed by the selected cells, h) the inner vertical borders formed by the selected cells, and i) the right borders formed by the selected cells.

The application may therefore include a process to determine the borders that apply to each border type. The same or a similar process may be used to determine the set of table cell edges (i.e. borders) in step 504 of the process 500.

In some embodiments, a process to determine the borders for editing and/or for step 504 includes first grouping the selected cells. The groups of selected cells are referred to herein as “buckets”. Once the selected cells have each been allocated to a bucket, borders for each bucket are determined, for each border type.

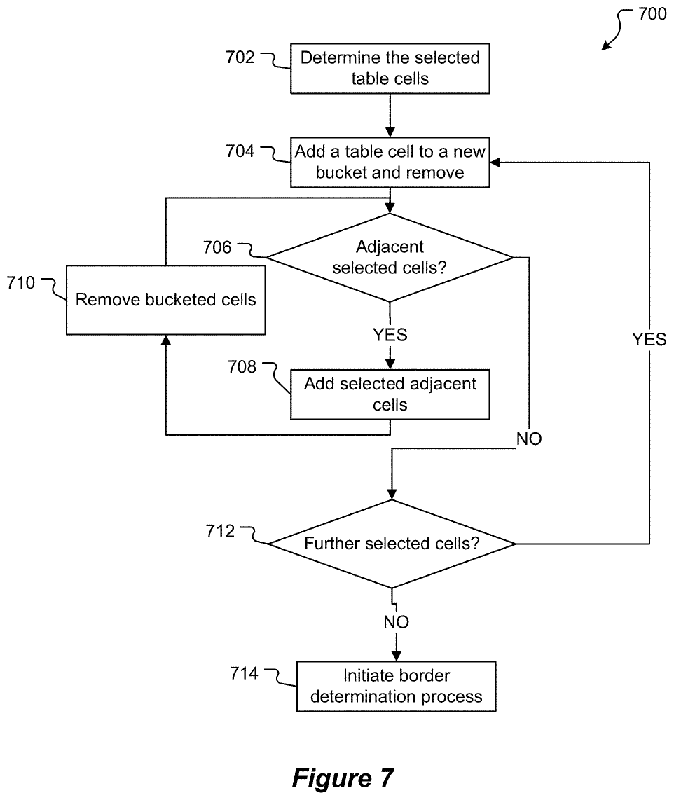

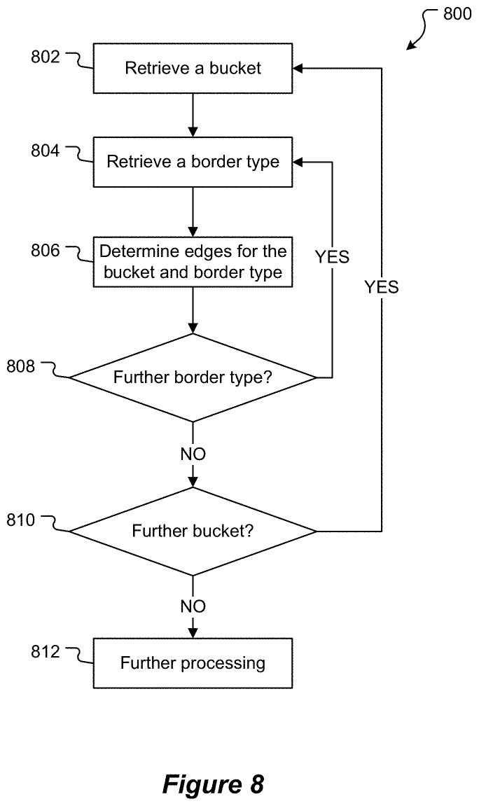

FIG. 7 shows a flow diagram of a process 700 for an application running on a computer processing system to group cells into buckets. As described above, in some embodiments the process 700 is part of the process for an application to determine the set of table cell edges in step 504 of the process 500. The process may be performed whilst a computer processing system, for example the computer processing system 200, is causing the display, on a display device, of a table. For example, the process may be performed whilst a table is displayed on the canvas 304 of the GUI 300.

In step 702 the process includes determining the selected table cells. The determination may correspond to or be based on received user input selecting cells, for example user input as described with reference to step 50 of the process 500. Identification of the determined selected table cells is stored in memory by the computer processing system. For convenience of explanation the stored identification of cells is referred to as a list of selected table cells. However, the stored identification need not be in a list form.

In step 704 a new bucket is formed and an initial table cell is removed from the list of selected table cells and added to the bucket. The initial table cell may be any cell that is currently in the list of selected table cells. The cell may be randomly or quasi-randomly selected, or selected according to a rule, for example the leftmost and uppermost cell that has been selected.

In step 706 the computer processing system determines which, if any, of the table cells in the list of selected table cells are adjacent to a table cell in the bucket (which on the first iteration is only the initial table cell). For a rectangular table, the adjacent cells to a table cell may be the cells immediately to the left, the right, the top and the bottom. Each table cell that is in the list and which is adjacent to a table cell in the bucket is then added to the bucket in step 708. In step 710 the table cells added to the bucket are removed from the list of selected table cells.

The process then repeats or iterates. For example step 706 is performed again with reference to the updated list of selected table cells. The repeat or iteration of the process continues until no further adjacent table cells are found in the list of selected table cells, at which point the process moves to step 712.

In step 712 the computer processing system determines whether there are any table cells left in the list of selected table cells. If so, the process returns to step 704 and another table cell from the list is added to a new bucket, which table cell will be the initial table cell for the new bucket. The process then cycles through steps 706 to 712 until it is determined in step 712 that there are no further table cells in the list of selected table cells. This ends a bucketing process and the computer processing system may then progress to a border determination process in step 714. As described above, the border determination process may be a process as per step 506 of the process 500 or a process to determine the borders that apply to each border type so that an editing operation can be performed.

FIG. 8 shows a flow diagram of a process 800 for an application. The process 800 may be performed by a computer processing system to implement the border determination process, for example step 506 of the process 500.

In step 802 the computer processing system retrieves a group of table cells from a selection of table cells. For example, the selection of table cells may a selection by a user of the computer processing system and the retrieved group of table cells may be a bucket formed using the process 700.

In step 804 a border type is retrieved. When process 800 is for a border determination process like that of step 506 of process 500, the border type is retrieved from a set of border types, the set containing the candidates for automatic selection. When the process 800 is for a table editing operation, the retrieved border type may be a border type corresponding to a selection by a user, for example a selection from the submenu 406 described with reference to FIG. 4.

In step 806 the computer processing system determines the cell edges for the table cells in the bucket retrieved in step 802 that are of a border type corresponding to the border type retrieved in step 804. Each border type is associated with a process implementing rules for completing step 806. A border type of every border of every selected cell will involve a rule of selecting every cell edge of every cell in the bucket.

In step 808 a determination is made whether there is a further border type to retrieve and process. For step 506 this determination will be “YES”, there is a further border type until all border types available for automatic selection have been processed in steps 804 and 806. For an editing operation, the determination will be “YES” if the user has selected a further border type, for example by selecting both the left and the right border options from submenu 406. If the determination of step 808 is “YES”, steps 804 to 808 are repeated for the next border type in relation to the same bucket. If the determination of step 808 is “NO”, the process moves to step 810.

In step 810, the computer processing system determines if there is another bucket of selected cells. If so, the process returns to step 802 and that bucket is processed to determine the edges for each relevant border type. If not the process moves to step 812, in which further processing is performed. The further processing may be steps 506 and 508 with respect to the cells edges for all buckets of the selection. The further processing may be the application of user selected attributes to the cell borders of each bucket identified in the one or more iterations of step 806.

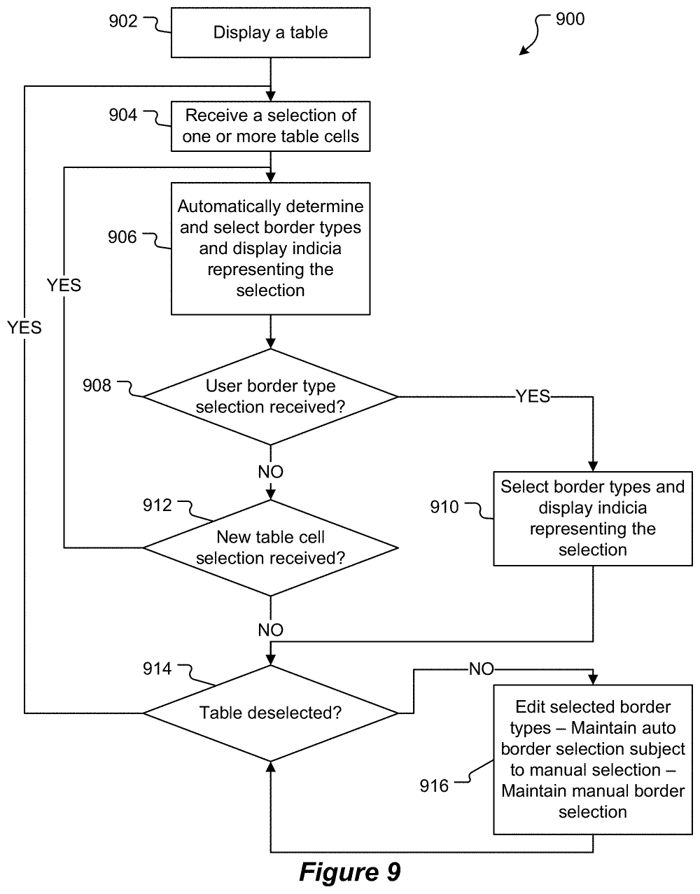

FIG. 9 shows a flow diagram of a process 900 for an application of a computer processing system to render and edit a table. In step 902 the computer processing system, for example the computer processing system 200, causes a display device to display a table. For example, the table is displayed on the canvas 304 of the GUI 300. The process 900 is performed while the table is displayed.

In step 904, the computer processing system receives an input indicating a selection of one or more table cells of the displayed table. The input may be based on user operation of a user interface object, such as a peripheral device, touch screen or similar.

In step 906, the computer processing system automatically determines and selects border types based on the received selection of border cells. The GUI may include indicia showing the selected border types. Step 906 may include or consist of implementing the process described with reference to FIG. 5.

In step 908, the computer processing system determines if a user input selecting borders for the selected cells has been received. If so, the process moves to step 910, in which border types corresponding to those of the user input are selected and indicia showing the selected border types is displayed. Any border types selected in step 906 that do not correspond to the user selection are deselected.

If in step 908 the computer processing system determines that a user input selecting borders has not been received, the process moves to step 912. In step 912, the computer processing system determines whether the user has made another selection of one or more table cells. If so, the process returns to step 906 and a new automatic border type selection is made for the new selected one or more table cells. The selected borders may therefore automatically change responsive to a user changing the cells selected in a table. If a new table cell selection is not received, the process moves to step 914.

In step 914, the computer processing system determines whether the user has deselected the table. If so, the state of the computer processing system is returned to the state of step 902 and the process 900 ends, other than continuing to display the table, subject to user input. A new selection of one or more table cells in a table will recommence the process according to step 904.

If in step 914 it is determined that the table remains selected, in step 916 the computer processing system receives one or more edit commands and edits borders of the selected border type or selected border type responsive to the edit commands. As will be appreciated from the foregoing description of the process 900, the selected border type or types are determined by either automatically as per step 906 or manually as per step 910. If the border types were determined automatically, then border types are automatically updated with changes in the selected table cells. If a user selection of border type is received, then this overrides the automatic updating and the editing process maintains the manual selection. If the border types were determined manually, then the border types are maintained with changes in the selected table cells. If the user deselects the table, as per step 914 then the process reverts to automatic selection, when a new selection of table cells for the same table or another table is received in step 904.

In the above embodiments the operations may be performed by the client system 130 (e.g. under control of the client application 132). Variations are, however, possible. For example in certain cases an operation performed by client system 130 may be performed instead at the server environment 110. Generally speaking, however, where user input is required such user input is initially received at client system 130 (by an input device thereof). The user input (or data representative of that input) may be processed by one or more applications running on client system 130 or may be communicated to server environment 110 for one or more applications running on the server hardware 112 to process. Similarly, data or information that is to be output by a client system 130 (e.g. via display, speaker, or other output device) will ultimately involve that system 130. The data/information that is output may, however, be generated (or based on data generated) by client application 132 and/or the server environment 110 (and communicated to the client system 130 to be output).

Furthermore, in certain implementations a computer processing system 200 may be configured (by an application running thereon) to perform the processing described herein entirely independently of a server environment 110. In this case, the application running on that system is a stand-alone application and all instructions and data required to perform the operations described above are stored on that computer processing system 200 (or devices connected thereto).

The flowcharts illustrated in the figures and described above defines operations in a particular order to explain various features. In some cases the operations described and illustrated may be able to be performed in a different order to that shown/described, one or more operations may be combined into a single operation, a single operation may be divided into multiple separate operations, and/or the function(s) achieved by one or more of the described/illustrated operations may be achieved by one or more alternative operations.

It will be understood that the embodiments disclosed and defined in this specification extend to alternative combinations of two or more of the individual features mentioned in or evident from the text or drawings. All of these different combinations constitute alternative embodiments of the present disclosure.

The present specification describes various embodiments with reference to numerous specific details that may vary from implementation to implementation. No limitation, element, property, feature, advantage or attribute that is not expressly recited in a claim should be considered as a required or essential feature. Accordingly, the specification and drawings are to be regarded in an illustrative rather than a restrictive sense.

1. A computer implemented method for providing a graphical user interface for editing a design, the method including:
causing display, on a display device, of a user interface for editing a design;
causing display, in the user interface, of a design formed by a plurality of design elements, wherein each of the plurality of design elements is associated with one or more attribute values that define how the design element is displayed;
receiving a selection of a plurality of the design elements;
determining a subset of the selected design elements;
automatically selecting one or more first edit operations for the selected design elements based on the determined subset of the selected design elements and not automatically selecting one or more second edit operations for the selected design elements based on the determined subset of the selected design elements; and
in response to receiving an edit command, editing at least one attribute value of the subset of the selected design elements in accordance with the one or more first edit operations.

2. The method of claim 1, further including displaying in the user interface indicia representing the automatically selected one or more first edit operations.

3. The method of claim 2, wherein the edit command includes or consists of selection of one or more attribute values and wherein the step of editing at least one attribute value of the subset of the selected design elements includes changing the at least one attribute value to the selected one or more attribute values.

4. The method of claim 1, wherein determining a subset of the selected design elements includes:
identifying a plurality of different subsets of the selected design elements;
comparing one or more attribute values of design elements in each of the identified different subsets to a reference, wherein the reference includes or consists of one or more attribute values;
determining the subset of the selected design elements based on the comparison.

5. The method of claim 4, wherein the reference is based on or specific to the design.

6. The method of claim 4, further including determining the reference before performing the comparing, wherein determining the reference includes determining the one or more attribute values forming the reference as matching a majority of the one or more attribute values across the plurality of design elements forming the design.

7. The method of claim 6, wherein determining the subset of the selected design elements based on the comparison includes determining that the subset of the selected design elements has a threshold number of design elements associated with unique attribute values relative to the reference.

8. The method of claim 7, wherein the threshold number of design elements is all design elements of the subset.

9. The method of claim 4, further including updating the reference based on the design after the editing.

10. The method of claim 9, wherein the reference corresponds to or is a global style for the design and the method comprises defining at least some of the plurality of design elements forming the design by the global style.

11. The method of claim 10, including redefining at least one of the plurality of design elements that are defined by the global style responsive to a change to the reference.

12. The method of claim 4, further including determining a further subset of the selected design elements based on the comparison, automatically selecting one or more third edit operations for the selected design elements based on the determined further subset of the selected design elements, and in response to receiving an edit command, both editing at least one attribute value of the subset of the selected design elements in accordance with the one or more first edit operations and editing at least one attribute value of the further subset of the selected design elements in accordance with the one or more third edit operations.

13. The method of claim 1, wherein the plurality of design elements forming the design include a first plurality of design elements in a first category of design elements and a second plurality of design elements in a second category, different to the first category and wherein:
the design elements of the subset of the selected design elements are of the first category and not the second category;
the one or more first edit operations for the selected design elements is or are operations for editing the first category of design elements and not for editing the second category of design elements.

14. The method of claim 1, wherein:
the design is a table formed by a plurality of cells and the plurality of design elements are borders of cells;
the one or more attribute values that define how the design element is displayed define at least one of a colour, a weight and a style of the border;
the selection of a plurality of the design elements is a selection of one or more of the plurality of cells;
the subset of the selected design elements is defined by one or more border types;
the one first edit operations are operations to change at least one attribute value of borders of the one or more border types and not operations to change other border types.

15. A computer implemented method for providing a graphical user interface for editing a design including or consisting of a table, the method including:
causing display, on a display device, of a user interface for editing a design;
causing display, in the user interface, of a table formed by a plurality of cells, each cell having a plurality of borders, wherein each of the plurality borders is associated with one or more attribute values that define how the border is displayed;
receiving a selection of one or more cells;
determining at least one subset of borders of the selected cells;
automatically selecting one or more first border edit operations based on the determined subset of borders and not automatically selecting one or more second border edit operations based on the determined subset borders; and
in response to receiving an edit command, editing at least one attribute value of the subset of borders in accordance with the one or more first edit operations.

16. The method of claim 15, wherein the at least one subset of borders of the selected cells is one or more, but not all, of: the top borders formed by the selected cells, the inner horizontal borders formed by the selected cells, the bottom borders formed by the selected cells, the left borders formed by the selected cells, the inner vertical borders formed by the selected cells, and the right borders formed by the selected cells.

17. The method of claim 15, wherein the at least one subset of borders of the selected cells is the top borders formed by the selected cells and the one or more first border edit operations is an operation that edits the top borders of selected cells.

18. The method of claim 15, wherein the at least one subset of borders of the selected cells is the bottom borders formed by the selected cells and the one or more first border edit operations is an operation that edits the bottom borders of selected cells.

19. The method of claim 15, wherein the at least one subset of borders of the selected cells is the left or right borders formed by the selected cells and the one or more first border edit operations is an operation that edits the left or right borders of selected cells respectively.

20. The method of claim 15, wherein the at least one subset of borders of the selected cells is some or all of the inner borders formed by the selected cells and the one or more first border edit operations is an operation that edits the some or all of the inner borders of selected cells.

21. The method of claim 15, wherein the at least one subset of borders of the selected cells is the outer borders formed by the selected cells and the one or more first border edit operations is an operation that edits the outer borders of selected cells.
